(19) United States
(12) Patent Application Publication
(10) Pub. No.: US 2014/0284090 A1
(43) Pub. Date: Sep. 25, 2014

(54) THIN FILM SUBSTRATE AND METHOD FOR MANUFACTURING THE SAME

(71) Applicant: ECOCERA Optronics Co., Ltd., Taoyuan County (TW)

(72) Inventors: Cheng-Feng Chou, Taoyuan County (TW); Ssu-Yu Chen, Taoyuan County (TW); Ming-Hsin Hsu, Taoyuan County (TW)

(73) Assignee: ECOCERA Optronics Co., Ltd., Taoyuan County (TW)

(21) Appl. No.: 14/206,064

(22) Filed: Mar. 12, 2014

(30) Foreign Application Priority Data
Mar. 22, 2013 (TW) 102110391

(51) Int. Cl. H05K 3/10; H05K 1/02

(52) U.S. Cl. CPC H05K 3/107; H05K 1/02
USPC 174/258; 427/97.2; 174/250

(57) ABSTRACT

The invention provides a method for manufacturing a thin film substrate. The method comprises steps of: providing a substrate having at least one through hole; forming a first metallic layer on a surface of the substrate and the through holes; forming a resist layer and a first opening on the first metallic layer; forming a second metallic layer in the first opening and the through hole; removing the resist layer and a part of the first metallic layer to form a circuit layer and a plurality of grooves; forming a solder mask layer on the circuit layer and in the groove, and forming a second opening on the solder mask layer to expose a part of the circuit layer; and polishing the surface of the exposed circuit layer and the solder mask layer.

### BACKGROUND OF THE INVENTION

1. Field of the Invention

The present invention generally relates to a ceramic substrate, in particular to a method for manufacturing a thin film substrate of light emitting diodes.

2. Description of Related Art

A conventional method for manufacturing a thin film substrate of light emitting diodes at least comprises steps of laser drilling or mechanical drilling, plating a seed layer, exposure and development of laminating film, via filling plating, abrasive band grinding, stripping and etching, polishing treatment, exposure and development of screen printed solder mask layer and surface treatment. In the step of exposure and development of screen printed solder mask layer, a solder mask material is provided on a circuit layer 200 and the substrate 100 by screen printing to form a solder mask layer 300 shown in FIG. 1A, and the solder mask layer 300 on the circuit layer 200 is removed by exposure and development or etching. However, there may have a difference of height of the circuit layer 200 and the solder mask layer 300, for example the solder mask layer 300 is lower than the circuit layer 200. In the soldering, a tin solder 400 is provided on the circuit layer 200, and a void 500 is produced between the circuit layer 200 and the solder mask layer 300 shown in FIG. 1B. Due to the thermal expansion and contraction of the tin solder 400, such a void 500 may cause a break of the tin solder 400 so that the circuit layer 200 has a poor contact with the tin solder 400 and the yield of LED package is reduced. In the other hand, if the solder mask layer 300 is higher than the circuit layer 200, a poor effect of LED package may also be produced.

Also, if the solder mask layer 300 is not screen printed sufficiently in manufacture, a new solder mask layer cannot be printed on the solder mask layer 300 directly. It is necessary to remove the solder mask layer 300 before a new solder mask layer is printed. It is a strenuous work, and may increase the cost of manufacture.

### SUMMARY OF THE INVENTION

The present invention is provided to solve the problems of the prior art. One primary object and purpose of the invention is to provide a method for manufacturing a thin film substrate. The process that includes exposure and development of screen printed solder mask layer may be directly performed after a process including stripping and etching, and the polishing treatment and surface treatment that may be performed after the process including exposure and development of screen printed solder mask layer can reduce the surface roughness of the circuit and increase the yield of the solder mask layer in the present invention. The tin solder may not break easily after bonding. Also, the polishing treatment can remove abnormal residuum on the circuit layer and the scratches produced during the manufacture of the solder mask layer. The height of the solder mask layer is the same to the height of the circuit layer or the solder mask layer is slightly lower than the circuit layer. Therefore, the tin solder may not break easily after bonding so that the circuit layer has an excellent contact with the tin solder.

Another object of the invention is to provide a method for manufacturing a thin film substrate. If the solder mask layer is not screen printed sufficiently in manufacture, a new solder mask layer can be printed on the solder mask layer directly. It is not necessary to remove the solder mask layer before a new solder mask layer is printed.

In order to fulfill the object and purpose described above, the invention provides a method for manufacturing a thin film substrate comprising steps of providing a substrate; forming at least one through hole in the substrate; forming a first metallic layer on a surface of the substrate and the through hole; forming a resist layer and a first opening on the first metallic layer by a process including exposure and development of laminating film, wherein the first opening may expose a part of the first metallic layer; forming a second metallic layer in the first opening and the through hole by a plating process; removing the resist layer; removing the first metallic layer other than beneath the second metallic layer to form a circuit layer and a plurality of grooves on the substrate; forming a solder mask layer on the circuit layer and in the groove by screen printing, and forming at least one second opening on the solder mask layer to expose a part of the circuit layer by a process including exposure and development; and polishing the surface of the exposed circuit layer and the solder mask layer to form a height of the solder mask layer being the same to the height of the circuit layer or the solder mask layer being slightly lower than the circuit layer.

In order to fulfill the object and purpose described above, the invention provides a thin film substrate for die bonding comprising: a substrate having a die bonding area; a circuit layer disposed on a surface of the substrate, the circuit layer having a plurality of grooves thereon, and each groove exposing a part of the substrate; and a solder mask layer disposed in the groove, wherein a height of the solder mask layer is the same to a height of the circuit layer or the solder mask layer is slightly lower than the circuit layer, and the solder mask layer is substantially the same to the circuit layer in the surface roughness.

### BRIEF DESCRIPTION OF DRAWING

FIG. 1A shows schematically drawn a cross sectional structure obtained in a process of manufacturing a screen printed solder mask layer of a conventional thin film substrate by exposure and development.

FIG. 1B shows a schematic view of a tin solder bonding to the circuit layer of a conventional thin film substrate.

FIG. 2 is a flow chart of a method for manufacturing a thin film substrate according to the invention.

FIG. 3 shows schematically drawn a cross sectional structure obtained in a process of manufacturing through holes in a substrate and a metallic layer on the substrate according to the invention.

FIG. 4 shows schematically drawn a cross sectional structure obtained in a process of manufacturing a resist layer on the substrate according to the invention.

FIG. 5 shows schematically drawn a cross sectional structure obtained in a process of manufacturing a circuit layer on the substrate according to the invention.

FIG. 6 shows schematically drawn a cross sectional structure obtained after a process of removing the resist layer and a part of the metallic layer on the substrate according to the invention.

FIG. 7 shows schematically drawn a cross sectional structure obtained in a process of screen printing a solder mask layer on the substrate according to the invention.

FIG. 8 shows schematically drawn a cross sectional structure obtained in a process of exposure and development to the solder mask layer on the substrate according to the invention.

FIG. 9 shows schematically drawn a cross sectional structure obtained in a process of removing the solder mask layer on the circuit layer according to the invention.

FIG. 10 shows schematically drawn a cross sectional structure obtained in a process of polishing the circuit layer and the solder mask layer on the substrate and surface treating the circuit layer according to the invention.

FIG. 11 is a schematic view of a tin solder bonding to the circuit layer according to the invention.

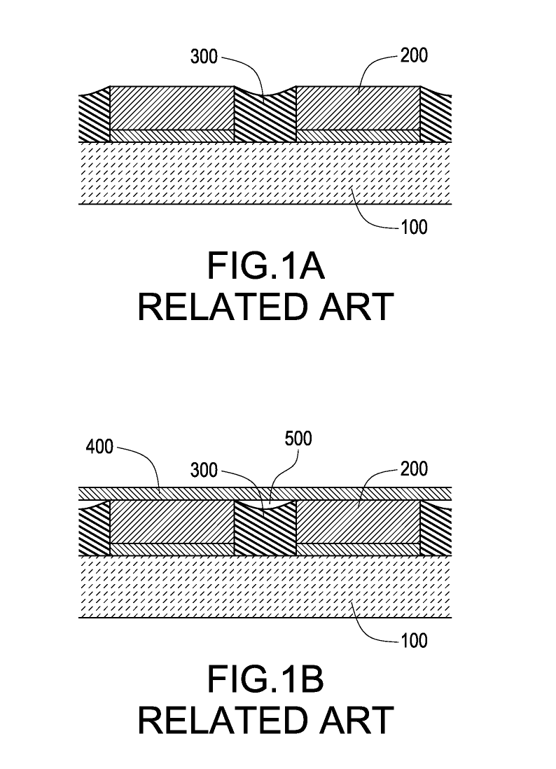

### DETAILED DESCRIPTION OF THE INVENTION

In cooperation with attached drawings, the technical contents and detailed description of the present invention are described thereinafter according to a preferable embodiment, being not used to limit its executing scope.

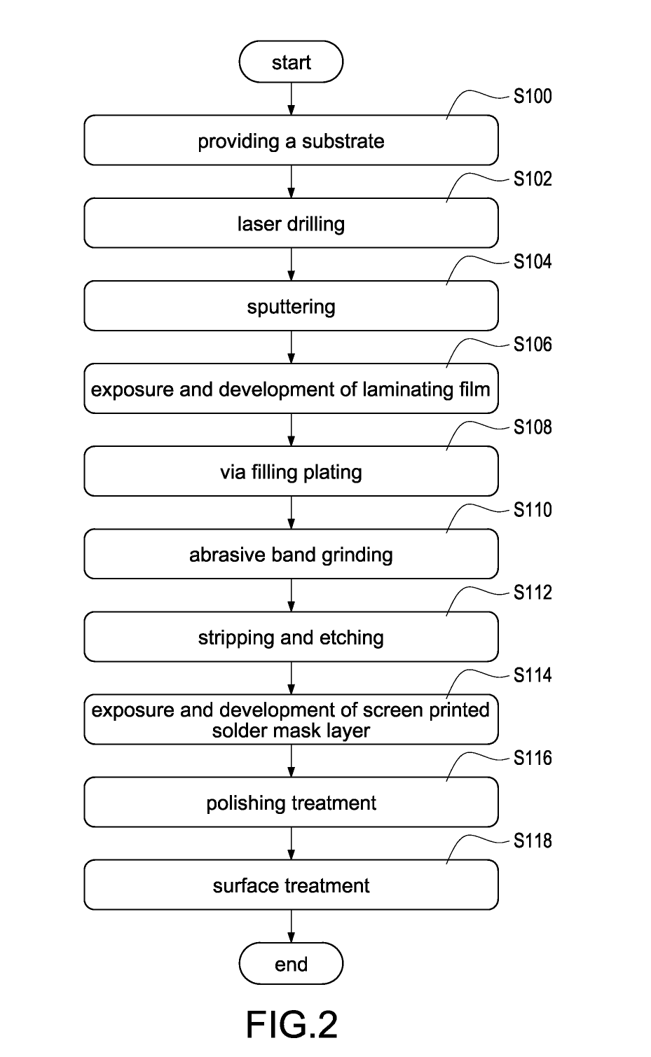

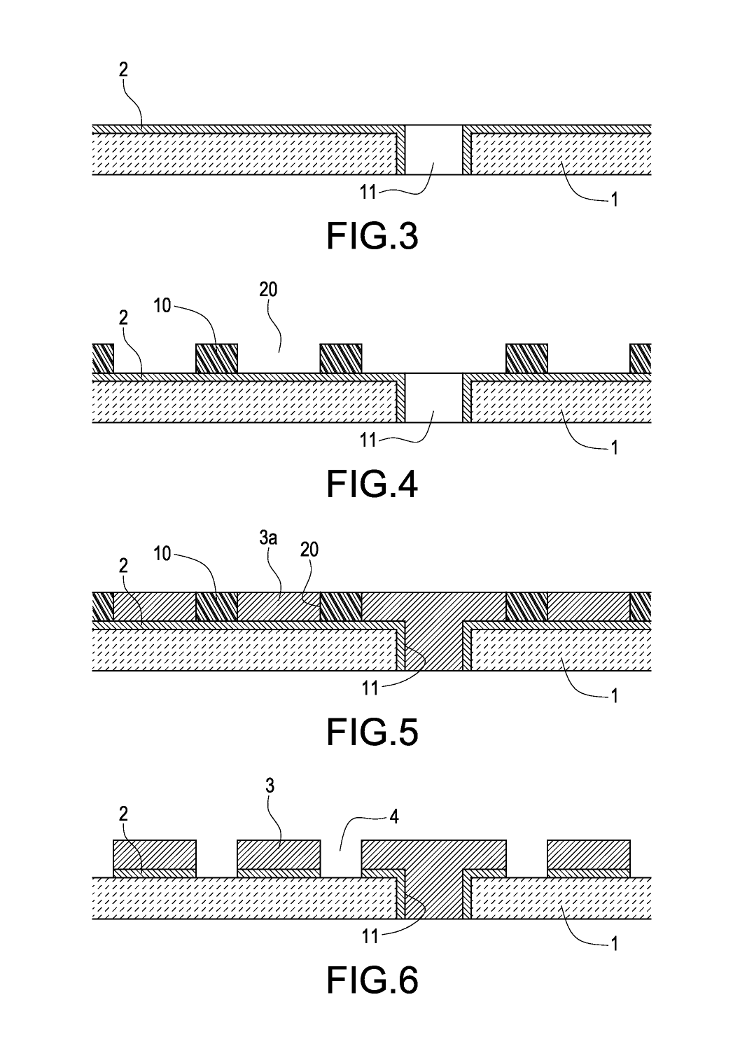

Please refer to FIG. 2 and FIGS. 3-10. FIG. 2 is a flow chart of a method of manufacturing a thin film substrate according to a preferred embodiment of the present invention. FIGS. 3-10 show schematically drawn step sequential cross sectional structures obtained in a process of manufacturing a thin film substrate according to a preferred embodiment of the present invention. At first, in step S100, a substrate 1 is provided. In the embodiment, the substrate 1 is made of ceramic material or glass fiber material.

In step S102, laser drilling is performed. In the embodiment, a focused high temperature laser is used to drill holes in the substrate 1 by vaporization. A plurality of through holes 11 are formed in the substrate 1, shown in FIG. 3. In step S102, a process of mechanical drilling can also be used to form at least one through hole 11 in the substrate 1.

In step S104, a sputtering process is performed. Titanium and copper materials may be plated sequentially on a surface of the substrate 1 and the through hole 11 to form a first metallic layer 2 by a sputtering process, shown in FIG. 3. After the sputtering process, an unimpeded through hole 11 auxiliary process including any one of electroless copper plating process, black hole process and conductive polymer process can be performed in order to avoid a poor metallization of through hole in case of a much small diameter in the sputtering process. In step S106, a process including exposure and development of laminating film is performed. A resist layer 10 and a first opening 20 may be formed on the first metallic layer 2 by the process of exposure and development of laminating film. The first opening 20 may expose a part of the first metallic layer 2, shown in FIG. 4.

In step S108, a via filling plating process is performed. Copper material is deposited in the first opening 20 and the through hole 11 to form a second metallic layer 3a, shown in FIG. 5.

In step S110, a process of abrasive band grinding is performed to remove melted slag and copper bumps, and improve unevenness of thickness and roughness after overplating so that surface of the substrate 1 is flat.

In step S112, a process including stripping and etching is performed. The resist layer 10 and a part of the first metallic layer 2 which are left after a process including exposure and development may be removed. After the resist layer 10 is removed, the exposed part of the first metallic layer 2 is removed by etching to form a circuit layer 3 and a groove 4 on the substrate 1. The groove 4 is formed to expose a part of substrate 1, shown in FIG. 6. In the embodiment, the circuit layer 3 is made of copper material. The circuit layer 3 at least includes a die bonding area and an electrode.

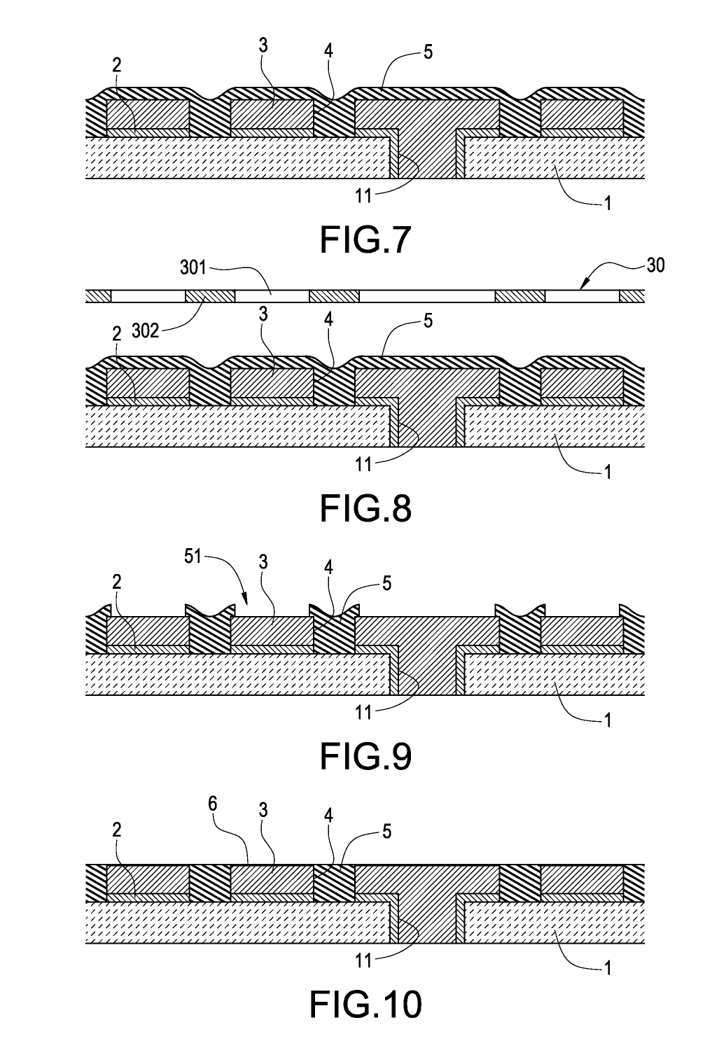

In step S114, a process including exposure and development of coated solder mask layer is performed. After the process including stripping and etching, a solder mask green painting or a solder mask white ink is coated on the circuit layer 3 and in the groove 4 to form a solder mask layer 5 by coating, for example screen printing or spray coating, shown in FIG. 7. The solder mask layer 5 is formed of polymer materials, for example epoxy, silicone and latex. As shown in FIG. 8, a photo mask 30 is provided over the solder mask layer 5. The photo mask 30 may have a light transmission section 301 and an opaque section 302, aligning the light transmission section 301 with the solder mask layer 5 disposed on the circuit layer 3 and aligning the opaque section 302 with the solder mask layer 5 disposed on the groove 4. The area of the opaque section 302 may slightly larger than the area of the groove 4 to ensure the solder mask layer 5 completely fills in the groove 4. For example, the width of the opaque section 302 is larger than the width of the groove 4 by 10 micrometers at each side. The process including exposure and development is performed when the light transmits to the solder mask layer 5 through the photo mask 30. As shown in FIG. 9, after the process including exposure and development is finished, at least one second opening 51 is formed on the solder mask layer 5. The second opening 51 is formed to expose a part of the circuit layer 3. In another embodiment, step S114 may be performed by forming a solder mask layer with at least one second opening on the circuit layer and in the groove by screen printing directly without the process including exposure and development.

In step S116, a polishing treatment is performed. The surface of the exposed circuit layer 3 and the solder mask layer 5 on the substrate 1 is polished by a polisher. Alternatively, surface of the exposed circuit layer 3 and the solder mask layer 5 on the substrate 1 is polished by polishing slurry (a weak acid solution). The polishing treatment is performed so that the height of the solder mask layer 5 is equal to or slightly lower than that of the circuit layer 3 shown in FIG. 10. In addition, the solder mask layer 5 is substantially the same to the circuit layer 3 in the surface roughness Ra≦0.1 um and/or Rz≦0.5 um. Also, the height difference is less than 1 micrometer between the electrodes of the circuit layer 3 on the die bonding area of the substrate 1 after polishing.

In step S118, a surface treatment is performed. The surface treatment is performed by plating at least one metallic material of Ag, Ni—Au and Ni—Pd—Au on the circuit layer 3 to form a metal bonding layer 6, shown in FIG. 10. The metal bonding layer 6 can not only increase the strength of the tin solder in the surface, but also increase the strength of bonding wire.

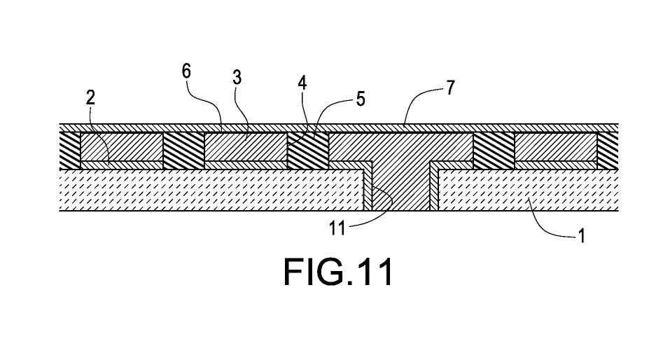

Please refer to FIG. 11 which is a schematic view of a tin solder bonding to the circuit layer according to the invention. As shown in FIG. 11, the thin film substrate comprises a substrate 1, a first metallic layer 2, a circuit layer 3, a solder mask layer 5 and a metal bonding layer 6.

The substrate 1 has a die bonding area. In the embodiment, the substrate 1 is made of ceramic material or glass fiber material. The method for manufacturing the solder mask layer of the invention can be applied in all LED thermal dissipation substrates, for example ceramic base copper clad laminate or metallic substrate.

The first metallic layer 2 is disposed on the surface of the substrate 1 and the through hole 11. In the embodiment, the first metallic layer 2 is of titanium and copper materials.

The circuit layer 3 is disposed on the surface of the first metallic layer 2 and formed a plurality of grooves 4. The groove 4 is formed to expose a part of substrate 1. In the embodiment, the circuit layer 3 is of copper material.

The solder mask layer 5 is formed in the groove 4. The height of the solder mask layer 5 in the groove 4 is the same to the height of the circuit layer 3. Alternatively, the solder mask layer 5 is slightly lower than the circuit layer 3. In addition, the solder mask layer 5 is substantially the same to the circuit layer 3 in the surface roughness Ra≦0.1 um and/or Rz≦0.5 um.

The metal bonding layer 6 is formed by plating at least one metallic material of Ag, Ni—Au and Ni—Pd—Au on the circuit layer 3. The metal bonding layer 6 can not only increase the strength of the tin solder in the surface, but also increase the strength of bonding wire.

In the soldering, a tin solder 7 is bonded on the circuit layer 3. Because the gap between the tin solder 7 and the solder mask layer 5 is extremely small so as to a void is not easily produced. Therefore, the tin solder 7 may not break easily after bonding so that the circuit layer 3 has an excellent contact with the tin solder 7.

Specifically, the polishing treatment which is performed after the process including exposure and development of screen printed solder mask layer can reduce the surface roughness of the circuit and increase the yield of the solder mask layer. The tin solder 7 may not break easily after bonding. Also, the polishing treatment can remove abnormal residuum on the circuit layer 3 and the scratches produced during the manufacture of the solder mask layer 5. The height of the solder mask layer 5 in the groove 4 is equal to the height of the circuit layer 3. Alternatively, the solder mask layer 5 is slightly lower than the circuit layer 3. Therefore, the tin solder 7 may not break easily after bonding so that the circuit layer 3 has an excellent contact with the tin solder 7. In addition, if the solder mask layer 5 is not screen printed sufficiently in manufacture, a new solder mask layer can be printed on the solder mask layer 5 directly. It is not necessary to remove the solder mask layer 5 before a new solder mask layer is printed.

What is claimed is:

1. A method of manufacturing a thin film substrate comprising steps of:
(a) providing a substrate;
(b) forming at least one through hole in the substrate;
(c) forming a first metallic layer on a surface of the substrate and the through hole;
(d) forming a resist layer and a first opening on the first metallic layer by a process including exposure and development of laminating film, wherein the first opening exposes a part of the first metallic layer;
(e) forming a second metallic layer in the first opening and the through hole by a plating process;
(f) removing the resist layer;
(g) removing the first metallic layer other than beneath the second metallic layer to form a circuit layer and a plurality of grooves on the substrate;
(h) forming a solder mask layer on the circuit layer and in the groove, wherein the solder mask includes at least one second opening to expose a part of the circuit layer; and
(i) polishing the surface of the exposed circuit layer and the solder mask layer to form a height of the solder mask layer being equal to or slightly lower than that of the circuit layer.

2. The method of manufacturing a thin film substrate of claim 1 wherein the substrate is made of ceramic material or glass fiber material.

3. The method of manufacturing a thin film substrate of claim 1 wherein the first metallic layer is made of titanium and copper materials.

4. The method of manufacturing a thin film substrate of claim 1 wherein the second metallic layer is made of copper material.

5. The method of manufacturing a thin film substrate of claim 1 wherein the solder mask layer is made of a solder mask green painting or a solder mask white ink.

6. The method of manufacturing a thin film substrate of claim 1 wherein the step (h) further comprises steps of providing a photo mask including a light transmission section and an opaque section, aligning the light transmission section with the solder mask layer disposed on the circuit layer, and aligning the opaque section with the solder mask layer disposed in the groove, wherein the area of the opaque section is larger than the area of the groove.

7. The method of manufacturing a thin film substrate of claim 6 wherein the width of the opaque section is larger than the width of the groove by 10 micrometers at each side.

8. The method of manufacturing a thin film substrate of claim 1 wherein in the step (i) the surface of the exposed circuit layer and the solder mask layer on the substrate is polished by a polisher.

9. The method of manufacturing a thin film substrate of claim 1 wherein in the step (i) the surface of the exposed circuit layer and the solder mask layer on the substrate is polished by polishing slurry.

10. The method of manufacturing a thin film substrate of claim 9 wherein the polishing slurry is a weak acid solution.

11. The method of manufacturing a thin film substrate of claim 1 wherein the step (c) comprises step (c1) of forming the first metallic layer on a surface of the substrate and the through hole by sputtering.

12. The method of manufacturing a thin film substrate of claim 11 wherein the step (c) comprises step (c2) of performing an unimpeded through hole auxiliary process including any one of electroless copper plating process, black hole process and conductive polymer process after step (c1).

13. The method of manufacturing a thin film substrate of claim 1 wherein the step (h) includes coating a solder mask layer on the circuit layer and in the groove, and forming at least one second opening on the solder mask layer to expose a part of the circuit layer by a process including exposure and development; or forming a solder mask layer with at least one second opening on the circuit layer and in the groove by screen printing.

14. A thin film substrate for die bonding comprising:
a substrate having a die bonding area;
a circuit layer disposed on a surface of the substrate, the circuit layer having a plurality of grooves thereon, and each groove exposing a part of the substrate; and
a solder mask layer disposed in the groove,
wherein a height of the solder mask layer is equal to or slightly lower than a height of the circuit layer, and the solder mask layer is substantially the same to the circuit layer in the surface roughness.

15. The thin film substrate for die bonding of claim 14 wherein the substrate is made of ceramic material or glass fiber material.

16. The thin film substrate for die bonding of claim 14 wherein the solder mask layer is made of a solder mask green painting or a solder mask white ink.

17. The thin film substrate for die bonding of claim 14 wherein a height difference between electrodes of the circuit layer on the die bonding area of the substrate is less than 1 micrometer.

18. The thin film substrate for die bonding of claim 14 wherein the solder mask layer is substantially the same to the circuit layer in the surface roughness Ra≦0.1 um and/or Rz≦0.5 um.
